(19) United States
(12) Patent Application Publication
(10) Pub. No.: US 2023/0286713 A1
(43) Pub. Date: Sep. 14, 2023

(54) BOWL, MEHTOD OF MANUFACTURING BOWL, AND APPARATUS FOR TREATING SUBSTRATE

(71) Applicant: SEMES CO., LTD., Cheonan-si (KR)

(72) Inventors: Hyun YOON, Hwaseong-si (KR); Ho Jong HWANG, Hwaseong-si (KR); Young Jin KIM, Seoul (KR)

(73) Assignee: SEMES CO., LTD., Cheonan-si (KR)

(21) Appl. No.: 17/693,807

(22) Filed: Mar. 14, 2022

(51) Int. Cl. B65D 65/38; B08B 3/02; B08B 13/00

(52) U.S. Cl. CPC B65D 65/38; B08B 3/022; B08B 13/00

(57) ABSTRACT

The present invention relates to a bowl including a collection container having an inner surface, and an outer surface disposed opposite to the inner surface, in which a pattern is formed on the inner surface.

### TECHNICAL FIELD

The present invention relates to a bowl, a method of manufacturing a bowl, and an apparatus for treating a substrate.

### BACKGROUND ART

In order to manufacture a semiconductor device or a liquid crystal display, various processes, such as photography, ashing, ion implantation, thin film deposition, and cleaning, performed on a substrate. Among them, the cleaning process is a process of removing particles remaining on the substrate, and progresses before and after each process.

FIG. 1 is a diagram illustrating a phenomenon in which droplets rebound by droplets attached to an inner surface of a bowl in the related art, and FIG. 2 is a diagram illustrating a contact angle (CA) between the inner surface of the bowl in the related art and the droplet.

Referring to FIGS. 1 and 2, the bowl 1 in the related art is made of PITE, which is a hydrophilic material. An inner surface 2 of the bowl 1 has a flat surface. A treatment liquid supplied to a rotating substrate W is scattered by rotational force and adheres to the inner surface 2 of the bowl 1. In this case, as illustrated in FIG. 2, as the inner surface 2 of the bowl 1 is made of a hydrophilic material, the hydrophilic contact area with the treatment liquid is increased to lower interface energy. Referring to FIG. 2, a contact angle A′ between the inner surface 2 of the bowl 1 in the related art and the droplet is 105°. As the contact area is small, the contact angle between the inner surface 2 of the bowl 1 and the droplet increases, and in this case, the amount of remaining droplets on the inner surface 2 of the bowl 1 increases. In this case, there is a problem in that the droplets scattered from the continuously rotating substrate W collide with the droplets attached to the inner surface 2 of the bowl 1, so that the droplets are re-scattered in the direction toward the substrate W. Further, there is a problem in that the substrate W is reversely contaminated due to the droplets rebounding to the substrate W.

In order to solve the problem, the method of manufacturing the bowl 1 in the related art by using a hydrophobic material and the method of coating or depositing the inner surface 2 of the bowl 1 with a hydrophobic material has been proposed. However, in the case of the bowl 1 used for cleaning, it is required to use a material with secured chemical resistance, heat resistance, and corrosion resistance, but there are few materials with sufficient chemical resistance, heat resistance, and corrosion resistance among the hydrophobic materials, there is a problem in that it is impossible to manufacture the bowl 1 by using the hydrophobic material. Further, in the case of the method of coating or depositing a hydrophobic component, chemical resistance, heat resistance, and corrosion resistance are weak, and there is a problem in that the substrate W is contaminated as the coating is peeled off.

### SUMMARY OF THE INVENTION

The present invention has been made in an effort to provide a bowl for preventing a substrate from being contaminated by scattering droplets that collide with an inner surface of the bowl during a substrate treatment, a method of manufacturing the bowl, and an apparatus for treating a substrate.

The object of the present invention is not limited thereto, and other objects not mentioned will be clearly understood by those of ordinary skill in the art from the following description.

An exemplary embodiment of the present invention provides a bowl, including: a collection container having an inner surface, and an outer surface disposed opposite to the inner surface, in which a pattern is formed on the inner surface.

According to the exemplary embodiment, the collection container may include a plurality of grooves depressed from the inner surface, and the pattern may be formed by continuously arranging the plurality of grooves.

According to the exemplary embodiment, the pattern may include a plurality of vertices formed between adjacent grooves among the plurality of grooves.

According to the exemplary embodiment, a distance between centers of two adjacent grooves among the plurality of grooves may be smaller than a depth of the groove.

According to the exemplary embodiment, the collection container may include a plurality of collection containers.

According to the exemplary embodiment, the plurality of collection containers may include: an internal collection container; an intermediate collection container disposed on the outside of the internal collection container; and an external collection container disposed on the outside of the intermediate collection container, and the pattern may be formed on an inner surface of each of the internal collection container, the intermediate collection container, and the external collection container.

According to the exemplary embodiment, the pattern may be formed over an entire region of the inner surface.

According to the exemplary embodiment, the pattern may be formed in a partial region of the inner surface.

According to the exemplary embodiment, the pattern may include a first pattern extended in a first direction parallel to a longitudinal direction of the collection container.

According to the exemplary embodiment, the pattern may include a second pattern extended in a second direction perpendicular to a longitudinal direction of the collection container.

According to the exemplary embodiment, the pattern may include a first pattern extended in a first direction parallel to a longitudinal direction of the collection container, and a second pattern extended in a second direction perpendicular to the first direction.

Another exemplary embodiment of the present invention provides a method of manufacturing a bowl, the method including: preparing a collection container made of a PTFE material; and forming a pattern by irradiating a laser on an inner surface of the collection container.

According to the exemplary embodiment, the pattern may include a plurality of grooves depressed from the inner surface, and the laser may be irradiated while moving in any one direction between a first direction parallel to a longitudinal direction of the collection container and a second direction perpendicular to the first direction.

According to the exemplary embodiment, the pattern may be formed by continuously arranging the plurality of grooves.

According to the exemplary embodiment, a radio of a depth of the groove and a diameter of the laser may be larger than 1:1.

According to the exemplary embodiment, as power of the laser increases, hydrophobicity of the bowl may increase.

According to the exemplary embodiment, as the laser, a femtosecond laser or an attosecond laser may be used.

Another exemplary embodiment of the present invention provides an apparatus for treating a substrate, the apparatus including: a support unit configured to support the substrate; a nozzle configured to supply a treatment liquid onto the substrate; and a bowl configured to accommodate the support unit, in which a pattern is formed on an inner surface of the bowl.

According to the exemplary embodiment, the bowl may include a plurality of grooves depressed from the inner surface, and the pattern may be formed by continuously arranging the plurality of grooves.

According to the exemplary embodiment, the pattern may include a plurality of vertices formed between adjacent grooves among the plurality of grooves.

According to the exemplary embodiment, a droplet of the treatment liquid scattered from a substrate rotated by the support unit may be attached to the inner surface of the bowl, and a contact angle between a virtual surface connecting the plurality of vertices and the droplet may be 150° or more.

According to the exemplary embodiment, the pattern may be formed in a partial region of the inner surface, and the pattern may be formed from an upper end of the bowl to a region corresponding to a process position of the substrate.

According to the bowl, the method of manufacturing the bowl, and the substrate treating apparatus according to the exemplary embodiment of the present invention, it is possible to prevent contamination of the substrate caused by scattering droplets that collide with the inner surface of the bowl during the substrate treatment.

Further, it is possible to realize super hydrophobicity even without changing the material through the patterning of the inner surface of the bowl with the laser.

Further, it is possible to remove the residual droplets by self-cleaning through the patterning of the inner surface of the bowl.

Further, through the patterning of the inner surface of the bowl, it is possible to prevent the phenomenon that the droplets rebound to the substrate.

The effect of the present invention is not limited to the foregoing effects, and those skilled in the art may clearly understand non-mentioned effects from the present specification and the accompanying drawings.

### BRIEF DESCRIPTION OF THE DRAWINGS

FIG. 1 is a diagram illustrating a phenomenon in which droplets rebound by droplets attached to an inner surface of a bowl in the related art.

FIG. 2 is a diagram illustrating a contact angle (CA) between the inner surface of the bowl in the related art and the droplet.

FIG. 3 is a top plan view illustrating a substrate treatment facility according to the present invention.

FIG. 4 is a cross-sectional view illustrating a substrate treating apparatus of FIG. 3.

FIG. 5 is an enlarged view of portion A of FIG. 4.

FIG. 6 is a diagram illustrating a CA between an inner surface of a bowl and a droplet according to the present invention.

FIGS. 7 to 9 are diagrams illustrating patterns formed on the inner surface of the bowl according to the present invention.

FIGS. 10 to 12 are diagrams illustrating a method of manufacturing a bowl according to the present invention.

FIG. 13 is a graph illustrating the amount of droplets scattering to the inner surface of the bowl in the related art.

FIG. 14 is a graph illustrating the amount of droplets scattering to the inner surface of the bowl according to the present invention.

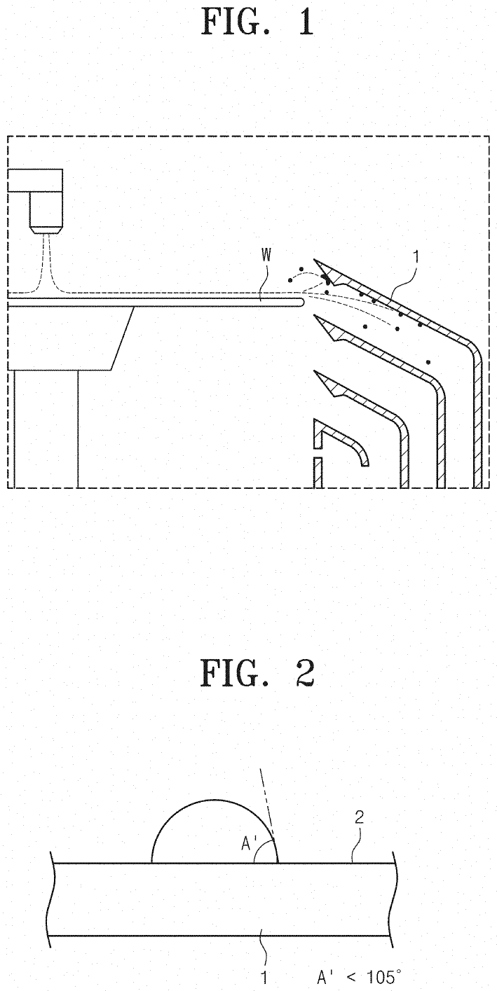

### DETAILED DESCRIPTION

An exemplary embodiment of the present invention may be modified in various forms, and the scope of the present invention should not be construed as being limited by the exemplary embodiment described below. The present exemplary embodiment is provided to more completely explain the present invention to those skilled in the art. Therefore, the shapes of components in the drawings are exaggerated to emphasize a clearer description.

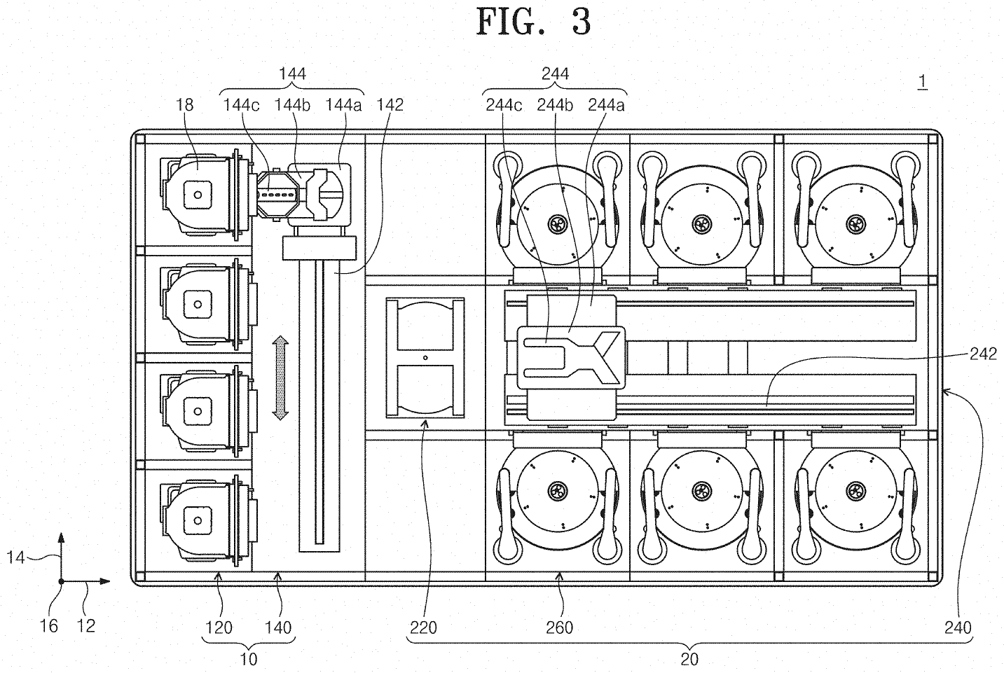

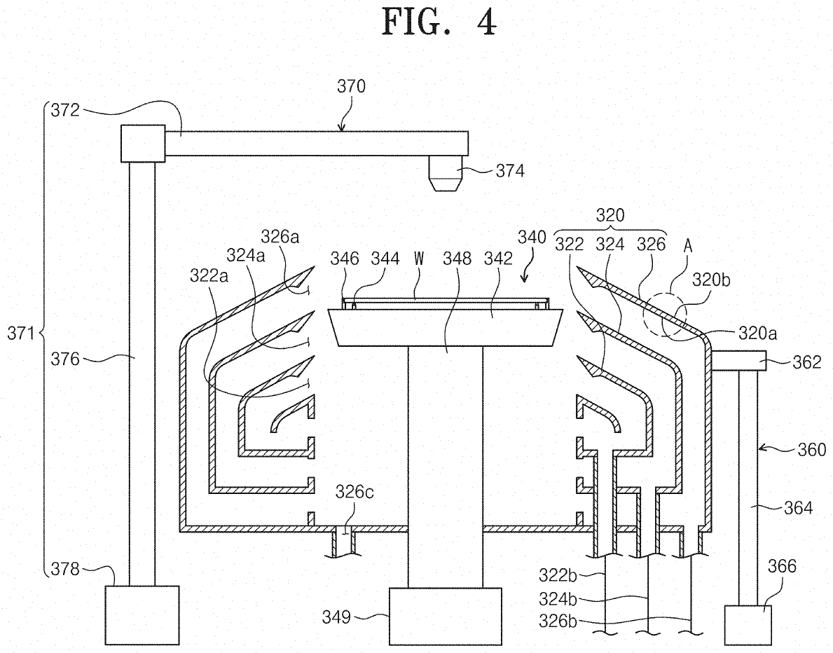

In the present exemplary embodiment, a substrate, a substrate support unit for supporting the substrate, and a process of cleaning a bowl surrounding the substrate will be described as examples. Hereinafter, an example of the present invention will be described in detail with reference to FIGS. 3 and 4.

FIG. 3 is a top plan view illustrating a substrate treatment facility according to the present invention, and FIG. 4 is a cross-sectional view illustrating a substrate treating apparatus of FIG. 3.

Referring to FIG. 3, a substrate treatment facility 1 may include an index module 10 and a process processing module 20. The index module 10 may include a load port 120 and a transfer frame 140. The load port 120, the transfer frame 140, and the process processing module 20 may be sequentially arranged in series. Hereinafter, a direction in which the load port 120, the transfer frame 140, and the process processing module 20 are arranged is referred to as a first direction 12, and a direction perpendicular to the first direction when viewed from above is referred to as a second direction 14, and a direction perpendicular to a plane including the first direction 12 and the second direction 14 is referred to as a third direction 16.

A carrier 18 in which a substrate W is accommodated may be seated in the load port 120. A plurality of load ports 120 may be provided. The plurality of load ports 120 may be disposed in series in the second direction 14. The number of load ports 120 may be increased or decreased according to process efficiency, a foot print condition, and the like of the process processing module 20. A plurality of slots (not illustrated) for accommodating the plurality of substrates W in a state arranged horizontally with respect to the ground may be formed in the carrier 18. The carrier 18 may include a Front Opening Unified Pod (FOUP).

The process processing module 20 may include a buffer unit 20, a transfer chamber 240, and a process chamber 260. The transfer chamber 240 may disposed so that a longitudinal direction thereof is parallel to the first direction. The process chambers 260 may be disposed at both sides of the transfer chamber 240. The plurality of process chambers 260 may be disposed at both sides of the transfer chamber 240 symmetrically to each other based on the transfer chamber 240. Some of the plurality of process chambers 260 may be disposed in the longitudinal direction of the transfer chamber 240. Further, some of the plurality of process chambers 260 may be disposed to be stacked on each other. That is, the plurality of process chambers 260 may be disposed in an arrangement of A×B at one side of the transfer chamber 240. Herein, A may mean the number of process chambers 260 provided in series in the first direction 12, and B may mean the number of process chambers 260 provided in series in the third direction 16. When four or six process chambers 260 are provided at one side of the transfer chamber 240, the process chambers 260 may be disposed in an arrangement of 2×2 or 3×2. However, the present invention is not limited thereto, and the number of process chambers 260 may be increased or decreased. Optionally, the process chamber 260 may be provided only to one side of the transfer chamber 240. Further, the process chambers 260 may be provided to one side or both sides of the transfer chamber 240 as a single layer.

The buffer unit 220 may be disposed between the transfer frame 140 and the transfer chamber 240. The buffer unit 220 may provide a space in which the substrate W stays before the substrate W is carried between the transfer chamber 240 and the transfer frame 140. Slots (not illustrated) on which the substrate W is placed may be provided to the inner side of the buffer unit 220. A plurality of slots (not illustrated) may be provided so as to be spaced apart from each other in the third direction 16. A surface of the buffer unit 220 facing the transfer frame 140 may be opened. A surface of the buffer unit 220 facing the transfer chamber 240 may be opened.

The transfer frame 140 may carry the substrate W between the carrier 18 that is seated on the load port 120 and the buffer unit 220. An index rail 142 and an index robot 144 may be provided to the transfer frame 140. The index rail 142 may be provided so that a longitudinal direction thereof is parallel to the second direction 14. The index robot 14 may be installed on the index rail 142. The index robot 142 may linearly move in the second direction 14 along the index rail 142.

The index robot 144 may include a base 144a, a body 144b, and an index arm 144c. The base 144a may be installed to be movable along the index rail 142. The body 144b may be coupled to the base 144a. The body 144b may be provided to be movable in the third direction 16 on the base 144a. Further, the body 144b may be provided to be rotatable on the base 144a. The index arm 144c may be coupled to the body 144b. The index arm 144c may be provided to be movable forwardly and backwardly with respect to the body 144b. A plurality of index arms 144c may be provided to be individually driven. The plurality of index arms 144c may be disposed to be stacked in the state of being spaced apart from each other in the third direction 16. A part of the plurality of index arms 144c may be used when the substrate W is carried from the process processing module 20 to the carrier 18. Another part of the plurality of index arms 144c may be used when the substrate W is carried from the carrier 18 to the process processing module 20. This may prevent particles generated from the substrate W before the process processing from being attached to the substrate W after the process processing in the process of loading and unloading the substrate W by the index robot 144.

The transfer chamber 240 may carry the substrate W. The transfer chamber 240 may carry the substrate W between the buffer unit 220 and the process chamber 260. The transfer chamber 240 may carry the substrate W between the process chambers 260. A guide rail 242 and a main robot 244 may be provided to the transfer chamber 240. The guide rail 242 may be disposed so that a longitudinal direction thereof is parallel to the first direction 12.

The main robot 244 may be installed on the guide rail 242. The main robot 244 may linearly move in the first direction 12 on the guide rail 242. The main robot 244 may include a base 244a, a body 244b, and a main arm 244c. The base 244a may be installed to be movable along the guide rail 242. The body 244b may be coupled to the base 244a. The body 244b may be provided to be movable in the third direction 16 on the base 244a. The body 244b may be provided to be rotatable on the base 244a. The main arm 244c may be coupled to the body 244b. The main arm 244c may be provided to be movable forwardly and backwardly with respect to the body 244b. A plurality of main arms 244c may be provided. The plurality of main arms 244c may be individually driven. The plurality of main arms 244 may be disposed to be stacked in the state of being spaced apart from each other in the third direction 16.

A substrate treating apparatus 300 may be provided to the process chamber 260. For example, the substrate treating apparatus 300 may perform a cleaning process on the substrate W. The substrate treating apparatus 300 may have a different structure according to the type of performed cleaning process. Contrary to this, the substrate treating apparatus 300 within each process chamber 260 may have the same structure. Optionally, the process chambers 260 are divided into a plurality of groups, and the substrate treating apparatuses 300 provided in the process chambers 260 belonging to the same group may have the same structure, and the substrate treating apparatuses 300 provided in the process chambers 260 belonging to different groups may have different structures.

The substrate treating apparatus 300 may perform a process of cleaning the substrate.

Referring to FIG. 4, the substrate treating apparatus 300 may include a bowl 320, a substrate support unit 340, a lift unit 360, a liquid supply unit 380, and a control unit (not illustrated).

The bowl 320 may have a cylindrical shape having an open top. The bowl 320 may have an internal collection container 322, an intermediate collection container 324, and an external collection container 326. The internal collection container 322, the intermediate collection container 324, and the external collection container 326 may collect different treatment liquids, respectively, among the treatment liquids used in the process.

The internal collection container 322 may be provided in an annular ring shape surrounding the substrate support unit 340. The internal collection container 322 may include an inner space 322a forming an inner portion. The inner space 322a may function as an inner inlet 322a through which a treatment liquid is introduced. The internal collection container 322 may be connected with a first collection line 322b. The first collection line 322b may be connected under the bottom surface of the inner inlet 322a. The first collection line 322b may be connected to a bottom plate of the internal collection container 322. The treatment liquid introduced through the inner inlet 322a may be discharged to the outside through the first collection line 322b. The treatment liquid introduced through the inner inlet 322a may be provided to an external treatment liquid regeneration system (not illustrated) through the first collection line 322b and re-used.

The intermediate collection container 324 may be provided in an annular ring shape surrounding the internal collection container 322. The intermediate collection container 324 may include an interspace 324a formed therein. The interspace 324a may be a space formed between the intermediate collection container 324 and the internal collection container 322. The interspace 324a may function as an intermediate inlet 324a through which the treatment liquid is introduced to the intermediate collection container 324. The intermediate collection container 324 may be connected with a second collection line 324b. The second collection line 324b may be connected under the bottom surface of the intermediate inlet 324a. The second collection line 324b may be connected to a bottom plate of the intermediate collection container 324. The treatment liquid introduced through the intermediate inlet 324a may be discharged to the outside through the second collection line 324b. The treatment liquid introduced through the intermediate inlet 324a may be provided to an external treatment liquid regeneration system (not illustrated) through the second collection line 324b and re-used.

The external collection container 326 may be provided in an annular ring shape surrounding the internal collection container 322. The external collection container 326 may include an inner exhaust hole 326c. The inner exhaust hole 326c may be formed in a bottom plate of the external collection container 326. The external collection container 326 may include an interspace 326a formed therein. The interspace 326a may be a space formed between the intermediate collection container 324 and the external collection container 326. The interspace 326a may function as an external inlet 326a through which the treatment liquid is introduced to the external collection container 326. The external collection container 326 may be connected with a third collection line 326b. The third collection line 326b may be connected under the bottom surface of the external inlet 326a. The third collection line 326b may be connected to a bottom plate of the external collection container 326. The treatment liquid introduced through the external inlet 326a may be discharged to the outside through the third collection line 326b. The treatment liquid introduced through the external inlet 326a may be provided to an external treatment liquid regeneration system (not illustrated) through the third collection line 326b and re-used.

The substrate treating apparatus 300 may include the substrate support unit 340. The substrate support unit 340 may support and rotate the substrate W during the process progress. The substrate support unit 340 may include a support plate 342, a support pin 344, a chuck pin 346, and rotation driving members 348 and 349. The substrate W may be disposed on the support plate 342. The support plate 342 may support the substrate W. The support plate 342 may be formed in a circular disk shape. The support plate 342 may include a top surface that is provided in a generally circular shape when viewed from above. A diameter of the top surface of the support plate 342 may be formed to be larger than a diameter of the substrate W. The support plate 342 may include a bottom surface disposed opposite to the top surface. The diameter of the bottom surface of the support plate 342 may be formed to be smaller than a diameter of the top surface of the support plate 342. In this case, a lateral surface connecting the top surface and the bottom surface of the support plate 342 may be inclined.

The rotation driving members 348 and 349 may rotate the support plate 342. The rotation driving members 348 and 349 may include the support shaft 348 and the driving unit 349. The support shaft 348 may be coupled to the support plate 342. One end of the support shaft 348 may be fixedly coupled to the bottom surface of the support plate 342. The support shaft 348 may support the support plate 342 under the support plate 342. The support shaft 348 may be provided to be rotatable about its central axis. In this case, the support shaft 348 may be rotated by the driving unit 349. In this case, the support plate 342 may be rotated together with the support shaft 342. The other end of the support shaft 342 may be coupled to the driving unit 349.

The driving unit 349 may be coupled to the support shaft 348. The driving unit 349 may provide driving force so that the support shaft 348 is rotated. The driving unit 349 may include a motor.

The support fin 344 may support the bottom surface of the substrate W. The support pin 344 may support the substrate W to be spaced apart from the top surface of the support plate 342 at a predetermined interval. The support pin 344 may protrude upward from the top surface of the support plate 342. The support pin 344 may be disposed in an edge region of the top surface of the support plate 342. A plurality of support pins 344 may be provided. The plurality of support pins 344 may be disposed while being spaced apart from each other. The plurality of support pins 344 may be disposed so as to have an annular ring shape as a whole by a combination with each other. The support pin 344 may support an edge of the bottom surface of the substrate W so that the substrate W is spaced a predetermined distance from the top surface of the support plate 342.

The chuck pin 346 may support a lateral surface of the substrate W. A plurality of chuck pins 346 may be provided. The chuck pin 346 may protrude upward from the top surface of the support plate 346. The chuck pin 346 may be disposed in an edge region of the top surface of the support plate 342. In this case, the chuck pin 346 may be disposed outside the support pin 344. The chuck pin 346 may be disposed farther from the center of the support plate 342 than the support pin 344. The chuck pin 346 may support the lateral portion of the substrate W so that the substrate W is not laterally separated from the original position when the substrate support unit 340 is rotated. A height of the chuck pin 346 in the axial direction of the support shaft 346 may be higher than the height in the corresponding direction of the support pin 344. Through this, the support pin 344 may support the bottom surface of the substrate W, and the chuck pin 346 may support the lateral surface of the substrate W. The chuck pin 346 may linearly move between a standby position and a supporting position along a radial direction of the support plate 342. In this case, the standby position may be a position further away from the center of the support plate 342 compared to the supporting position. The chuck pin 346 may be located at the standby position when the substrate W is loaded to or unloaded from the substrate support unit 340. The chuck pin 346 may be located at the supporting position when the process is performed on the substrate W. In this case, the chuck pin 346 is in contact with the lateral portion of the substrate W at the supporting position.

The substrate treating apparatus 300 may include the lift unit 360. The lift unit 360 may be coupled to a lateral wall of the bowl 320. The lift unit 360 may adjust a relative height between the substrate support unit 340 and the bowl 320. The lift unit 360 may linearly move the bowl 320 in a vertical direction. In this case, as the bowl 320 moves in the vertical direction, the relative height of the bowl 320 to the substrate support unit 340 may be changed. The lift unit 360 moves down so that the bowl 320 is lowered when the substrate W is placed on the substrate support unit 340 or the substrate W is lifted from the substrate support unit 340. In this case, the substrate support unit 340 may protrude above the bowl 320. The lift unit 360 may adjust the height of the bowl 320 so that the treatment liquid is introduced into the predetermined collection container 320 according to the type of treatment liquid that has been supplied to the substrate W when the process progresses. For example, when the treatment liquid is introduced to the external collection container 326, the lift unit 360 may move the bowl 320 in the vertical direction so that the external inlet 326a corresponds to the position of the substrate W. When the treatment liquid is introduced to the intermediate collection container 324, the lift unit 360 may move the bowl 320 so that the intermediate inlet 324a corresponds to the position of the substrate W. When the treatment liquid is introduced to the internal collection container 322, the lift unit 360 may move the bowl 320 in the vertical direction so that the inner inlet 322a corresponds to the position of the substrate W.

The lift unit 360 may include a bracket 362, a movement shaft 364, and a driving unit 366. The bracket 362 may be fixedly installed to the lateral wall of the bowl 320. One end of the bracket 362 may be fixed to the lateral wall of the external collection container 326 of the bowl 320. The other end of the bracket 362 may be coupled with the movement shaft 364. The movement shaft 364 may be moved in the vertical direction. The movement shaft 364 may be moved in the vertical direction by receiving power from the driving unit 366. In this case, the bracket 362 coupled to the movement shaft 364 and the bowl 320 coupled to the bracket 362 may be moved together with the movement shaft 364 in the vertical direction. The driving unit 366 may be coupled to the movement shaft 364. The driving unit 366 may provide power to the movement shaft 364. The driving unit 366 may include a motor.

The liquid supply unit 370 supplies various kinds of liquids onto the substrate W. One or more liquid supply units 370 may be provided. According to one example, a moving nozzle unit and a fixed nozzle unit may be included.

The liquid supply unit 370 supplies the treatment liquid onto the substrate W. The liquid supply unit 370 may be a moving nozzle unit or a fixed nozzle unit. According to the illustrated exemplary embodiment, the liquid supply unit 370 is a moving nozzle unit. A plurality of liquid supply units 370 may be provided. The plurality of liquid supply units 370 may be provided according to the type of treatment liquid. For example, each of the liquid supply units 370 may supply a different type of liquid. The treatment liquid may be a cleaning composition. The liquid supply unit 370 may include a nozzle 374 and a nozzle moving member 371. The nozzle 374 may move between a process position and a standby position. The nozzle 374 may move between the process position and the standby position by the nozzle moving member 371. Herein, the process position is a position where the nozzle 374 faces the substrate W supported by the substrate support unit 340, and the standby position is a position where the nozzle 374 is output of the process position. According to an example, the process position may be a position where the nozzle 374 is capable of supplying the liquid to the center of the substrate W. When viewed from above, the nozzle 374 may be positioned so that a discharge port matches the center of the substrate W in the process position.

The nozzle moving member 371 may include an arm 372, a support shaft 376, and a driving member 378. The nozzle 374 may be coupled to the arm 372. The nozzle 374 may be fixed to one end of the arm 372. The other end of the arm 372 may be coupled with the support shaft 376. The arm 382 may be coupled to an upper end of the support shaft 386. The arm 372 may be extended from the support shaft 376 in a horizontal direction. The arm 372 may be extended in a direction perpendicular to a longitudinal direction of the support shaft 376. The arm 372 is rotatable. Through this, the nozzle 374 fixed to the arm 372 may be swingably moved. The nozzle 374 may be swingably moved to the process position and the standby position.

The support shaft 376 may be disposed at one side of the bowl 320. The support shaft 376 may include a rod shape of which a longitudinal direction heads the third direction 16. One end of the support shaft 376 may be coupled to the arm 372. The other end of the support shaft 376 may be coupled to the driving member 378. The support shaft 376 may be provided to be rotatable by the driving member 378. In this case, the arm 372 fixed to the support shaft 376 may be rotated together with the support shaft 376. Optionally, the support shaft 376 may be provided to enable lifting and lowering movement. Further, the arm 372 may be provided to enable forward and backward movement in the longitudinal direction thereof.

The driving member 378 may be coupled to the support shaft 376. The driving member 378 may provide driving force to the support shaft 376. The driving member 378 may include a motor.

Hereinafter, a configuration of the bowl 320 according to the present invention will be described in more detail with reference to the drawings.

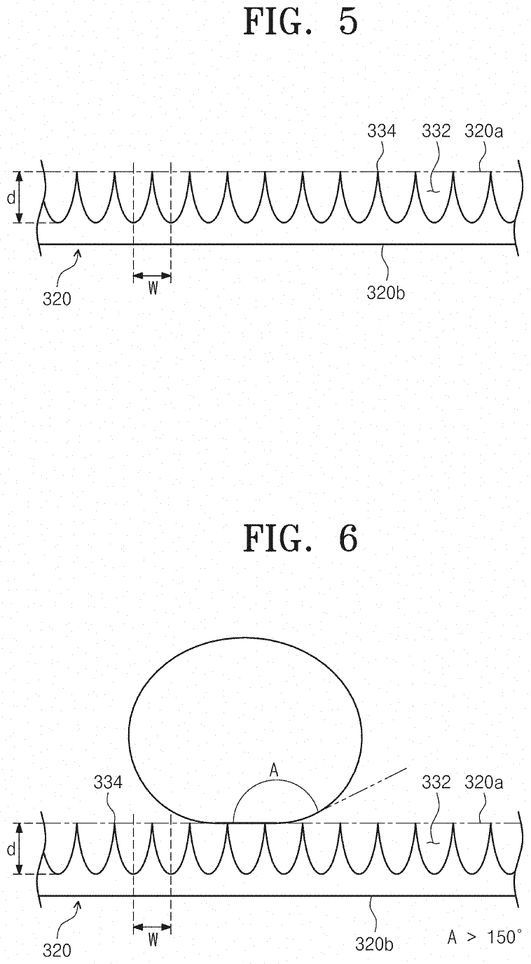

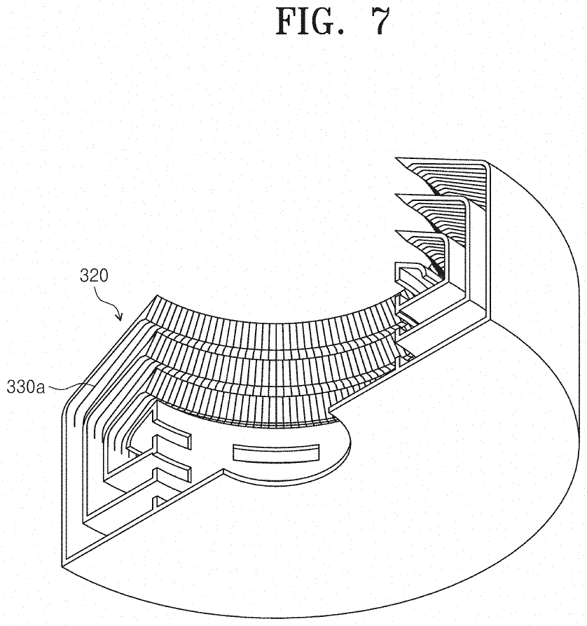

FIG. 5 is an enlarged view of portion A of FIG. 4, FIG. 6 is a diagram illustrating a CA between an inner surface of a bowl and a droplet according to the present invention, and FIGS. 7 to 9 are diagrams illustrating patterns formed on the inner surface of the bowl according to the present invention.

Referring to FIG. 5, the bowl 320 may include an inner surface 320a, and an outer surface 320b disposed opposite the inner surface 320a. Each of the internal collection container 322, the intermediate collection container 324, and the external collection container 326 may have the inner surface 320a and the outer surface 320b. A pattern 330 may be formed on the inner surface 320a of the bowl 320. The pattern may be formed on the inner surface 320a of each of the internal collection container 322, the intermediate collection container 324, and the external collection container 326. The bowl 320 may be formed of a PTFE material.

The pattern 330 may include a groove 332. The groove 332 may be formed to be rounded at least in part. However, the groove 332 is not limited thereto, and may be formed in various shapes according to a shape of an emitted laser 400. The groove 332 may be formed by being depressed from the inner surface 320a. The groove 332 may include a plurality of grooves 332. The plurality of grooves 332 may be continuously formed. The pattern 330 may include vertices 334 formed on the inner surface 320a of the bowl 320. The vertices 334 may be formed by the plurality of continuously grooves 332.

Referring to FIG. 5, a distance W between the centers of two adjacent grooves among the plurality of continuous grooves 332 may be smaller than a depth d of the groove 332. The distance W between the centers of two adjacent grooves among the plurality of continuous grooves 332 may be called as a pattern pitch interval. The pattern pitch interval W may be 50 μm or less. In the case of the bowl 320 made of the PTFE material, the smaller the pattern pitch interval W, the better the hydrophobic property may be realized. The deeper the depth d of the groove 332, the better the hydrophobic property may be realized. A ratio of the pattern pitch internal W and the depth d of the groove 322 may be larger than 1:1.

Referring to FIG. 6, a contact angle A between the inner surface 320a of the bowl 320 and a droplet scattering to the inner surface 320a may be 150° or more. Preferably, the contact angle A may be 170° or more. In this case, the contact angle A may mean an angle between a virtual surface connecting the plurality of vertices 344 and a tangent at a point at which the virtual surface connecting the plurality of vertices 344 is in contact with the droplet. The contact angle CA means an angle between the free surface of a liquid and a solid plane when the liquid and gas are thermodynamically equilibrium on the surface of the solid. The contact angle is mainly used as a measure of the wettability of a solid surface. The contact angle is measured by a sessible droplet. The low contact angle represents high wettability and high surface energy, and the high contact angle represents low wettability and low surface energy. In general, when a contact angle is measured as 90° or less, wettability is low, so that the bowl is hydrophilic, and when a contact angle is measured as 110° or more, wettability is high, so that the bowl is hydrophobic. In the case of the bowl made of the PTFE material, a contact angle between the inner surface of the bowl and the droplet is measured as about 105° to 110°. However, in the case of the bowl 320 according to the present invention, the contact angle by the pattern 330 of the inner surface 320a is 150 or more, to realize super hydrophobic.

Referring to FIG. 7, the pattern 330 may include a first pattern 330a extended in a first direction parallel to the longitudinal direction of the bowl 320. The first pattern 330a may include a plurality of first patterns 330a. The plurality of grooves 332 is continuously extended in the first direction to form the first pattern 330a. The plurality of first patterns 330a may be formed on the inner surface of each of the internal collection container 322, the intermediate collection container 324, and the external collection container 326.

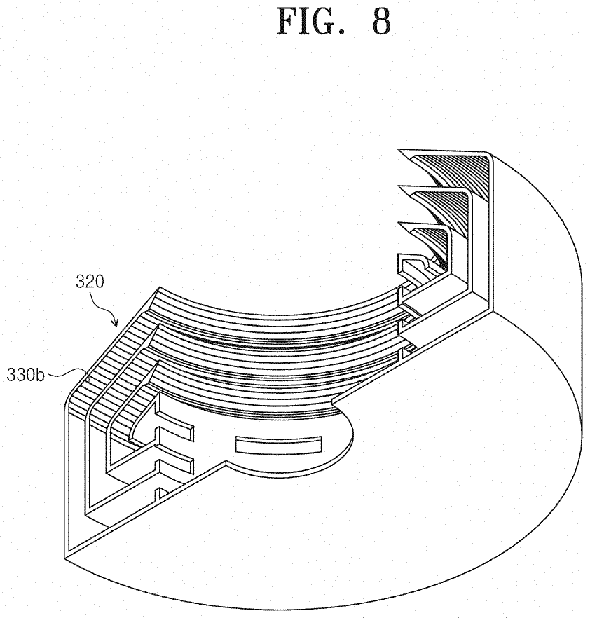

Referring to FIG. 8, the pattern 330 may include a second pattern 330b extended in a second direction perpendicular to the first direction of the bowl 320. In this case, the second direction may mean a circumferential direction of the bowl 320. The second pattern 330b may include a plurality of second patterns 330b. The plurality of grooves 332 is continuously extended in the second direction to form the second pattern 330b. The plurality of second patterns 330b may be formed on the inner surface of each of the internal collection container 322, the intermediate collection container 324, and the external collection container 326.

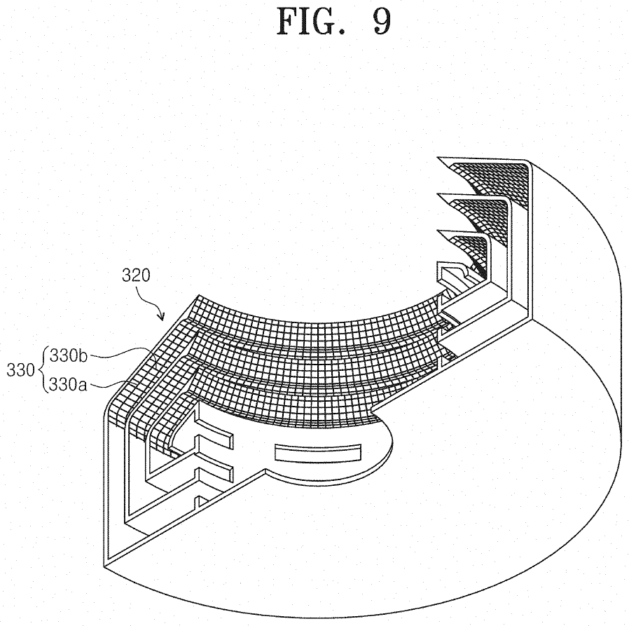

Referring to FIG. 9, the pattern 330 may include both a first pattern 330a extended in a first direction of the bowl 320, and a second pattern 330b extended in a second direction perpendicular to the first direction. The first pattern 330a may include a plurality of first patterns 330a. The second pattern 330b may include a plurality of second patterns 330b. The pattern 330 may be formed in a cross (+) shape by a combination of the plurality of first patterns 330a and the plurality of second patterns 330b. The plurality of first and second patterns 330a and 330b may be formed on the inner surface of each of the internal collection container 322, the intermediate collection container 324, and the external collection container 326.

Referring back to FIGS. 7 to 9, the pattern 330 may be formed in a partial region of the inner surface 320a. In particular, the pattern 330 may be formed from an upper end of the inner surface 320a to a region of the inner surface 320a of the bowl 320 corresponding to the support plate 342. In this case, the region of the inner surface 320a of the bowl 320 corresponding to the support plate 342 may mean a corresponding region in the process position. For example, when the treatment liquid supplied to the substrate W is introduced to the external inlet 326a of the external collection container 326, the pattern 330 may be formed to a region where the inner surface 320a of the external collection container 326 corresponds to the support plate 342. Further, when the treatment liquid supplied to the substrate W is introduced to the intermediate inlet 324a of the intermediate collection container 324, the pattern 330 may be formed to a region where the inner surface 320a of the intermediate collection container 324 corresponds to the support plate 342. Further, when the treatment liquid supplied to the substrate W is introduced to the inner inlet 322a of the internal collection container 322, the pattern 330 may be formed to a region where the inner surface 320a of the inner collection container 322 corresponds to the support plate 342.

As a modified example, the pattern 330 may be formed over an entire region of the internal surface 320a. In particular, the pattern 330 may be formed over the entire region of the internal surface 320a of each of the external collection container 326, the intermediate collection container 324, and the internal collection container 322.

Hereinafter, a method of manufacturing the bowl 320 according to the present invention will be described in detail with reference to the drawings.

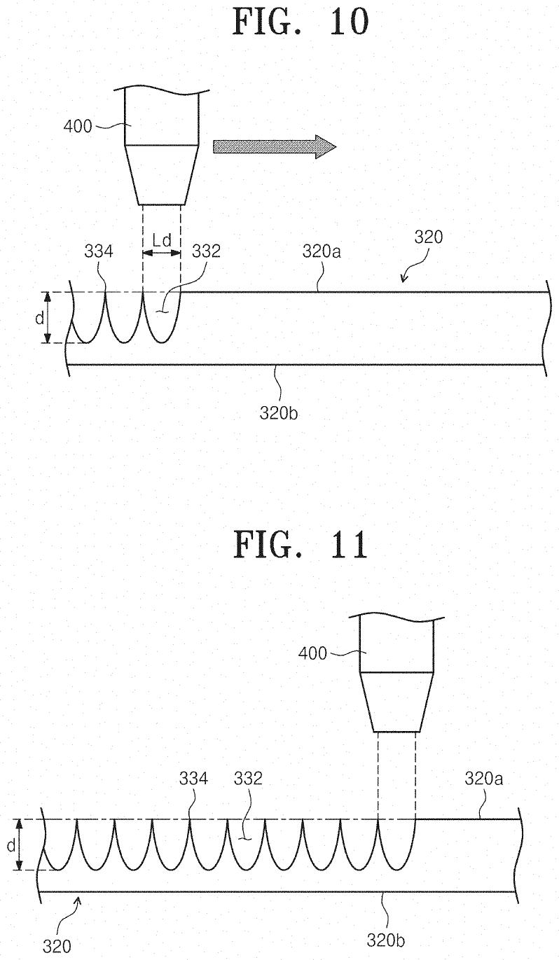

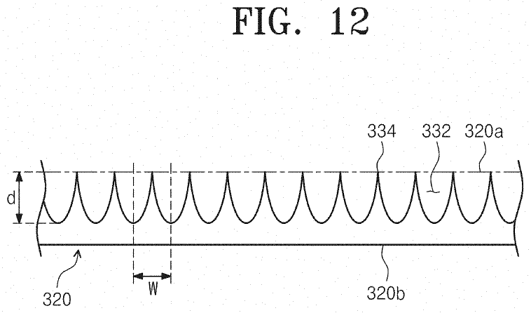

FIGS. 10 to 12 are diagrams illustrating a method of manufacturing the bowl according to the present invention.

Referring to FIGS. 10 to 12, a method of manufacturing the bowl 320 may include an operation of preparing the collection containers 322, 324, and 326 made of a PTFE material, and an operation of forming a pattern 300 by emitting a laser 400 to the inner surfaces 320a of the collection containers 322, 324, and 326.

The pattern 330 may include a plurality of continuous grooves 332, and a plurality of vertices formed between the plurality of grooves 332. The groove 332 may be formed by the laser 400. The laser 400 may be emitted while moving in any one direction between a first direction parallel to the longitudinal directions of the collection containers 322, 324, and 326 and a second direction perpendicular to the first direction. A diameter Ld of a laser beam emitted from the laser 400 may correspond to a maximum diameter W of the groove 332. A ratio of the diameter Ld of the laser beam and the depth d of the groove 322 may be larger than 1:1. As the laser 400, a femtosecond laser or an attosecond laser. When the patterning is performed with a nanosecond laser or a picosecond laser, there is a problem in that carbonization occurs. In the case of the present invention, the patterning work is performed by using the femtosecond laser or the attosecond laser, so that it is possible to prevent a color of the inner surface 320a of the bowl 320 from being changed, such as carbonization phenomenon. As the laser 400, the laser 400 having power greater than or equal to specific power may be used. In this case, the specific power may mean power appropriate to the PTFE material. As the power of the laser 400 increases, a hydrophobic property of the bowl 320 may be increased.

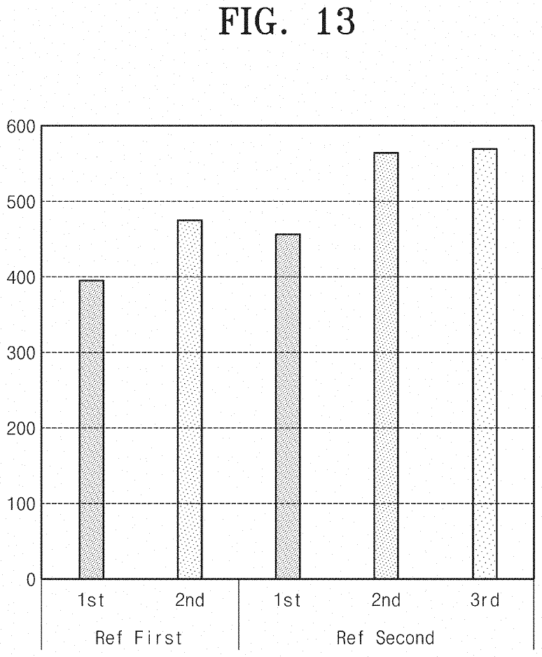

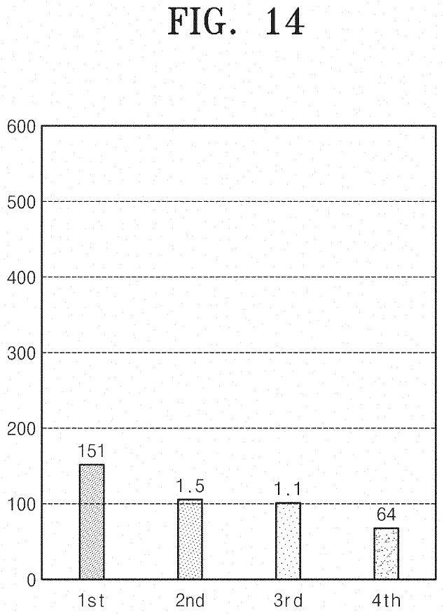

FIG. 13 is a graph illustrating the amount of droplets scattering to the inner surface of the bowl in the related art, and FIG. 14 is a graph illustrating the amount of droplets scattering to the inner surface of the bowl according to the present invention.

Referring to FIG. 13, scattering occurs on the inner surface 2 of the bowl 1 in the related art during a wet process with the substrate treating apparatus. 1st of a first experimental example (Ref first) means the number of droplets scattered in the state where the inner surface 2 of the bowl 1 is dried, and 2nd of the first experimental example (Ref first) means the number of droplets scattered in the state where the inner surface 2 of the bowl 1 is wet by an immediately previous wet process. Similarly, of 1st of a second experimental example (Ref second) means the number of droplets scattered in the state where the inner surface 2 of the bowl 1 is dried, 2nd of the second experimental example (Ref second) means the number of droplets scattered in the state where the inner surface 2 of the bowl 1 is wet by an immediately previous wet process, and 3rd means the number of droplets scattered in the wet state by the immediately previous wet process. Referring to the first experimental example (Ref first) and the second experimental example (Ref second), it can be seen that the number of scattering droplets is increased by about 20% or more in the wet-state bowl than that of the dry-state bowl. However, the same level of scattering droplets can be observed during processing in the state where the inside of the bowl is wet. Therefore, it can be seen that the problem of increasing the amount of scattering occurs due to the collision between the residual droplets remaining on the inner surface of the bowl and the scattering droplets that are scattered during the process.

In order to solve the problem, it is possible to implement the super hydrophobicity of the bowl 320 by forming the pattern 330 on the inner surface 320a by using the laser 400. FIG. 14 is the graph illustrating the number of scattering droplets of the inner surface 320a of the bowl 320 to which the hydrophobic pattern 330 is applied during the wet process with the substrate treating apparatus. Referring to FIG. 14, it can be seen that the number of scattering droplets is reduced by an average of 80% compared to the first and second experimental examples (Ref first, Ref second).

The bowl, the method of manufacturing the bowl, and the substrate treating apparatus according to the present invention are capable of preventing the substrate from being contaminated by scattering droplets that collide with the inner surface of the bowl during the substrate treatment. Further, it is possible to realize super hydrophobicity even without changing the material through the patterning of the inner surface of the bowl with the laser. Further, it is possible to minimize residual droplets remaining on the inner surface of the bowl by implementing the super hydrophobicity by patterning the inner surface of the bowl. Through this, it is possible to minimize the phenomenon that the droplets rebound due to the collision between the residual droplets and the scattering droplets. Further, it is possible to remove the residual droplets by self-cleaning through the patterning of the inner surface of the bowl. Further, through the patterning of the inner surface of the bowl, it is possible to prevent the phenomenon that the droplets rebound to the substrate.

The foregoing detailed description illustrates the present invention. Further, the above content shows and describes the exemplary embodiment of the present invention, and the present invention can be used in various other combinations, modifications, and environments. That is, the foregoing content may be modified or corrected within the scope of the concept of the invention disclosed in the present specification, the scope equivalent to that of the disclosure, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

1. A bowl comprising:
a collection container having an inner surface, and an outer surface disposed opposite to the inner surface,
wherein a pattern is formed on the inner surface.

2. The bowl of claim 1, wherein the collection container includes a plurality of grooves depressed from the inner surface, and
the pattern is formed by continuously arranging the plurality of grooves.

3. The bowl of claim 2, wherein the pattern includes a plurality of vertices formed between adjacent grooves among the plurality of grooves.

4. The bowl of claim 2, wherein a distance between centers of two adjacent grooves among the plurality of grooves is smaller than a depth of the groove.

5. The bowl of claim 1, wherein the collection container includes a plurality of collection containers.

6. The bowl of claim 5, wherein the plurality of collection containers includes:
an internal collection container;
an intermediate collection container disposed on the outside of the internal collection container; and
an external collection container disposed on the outside of the intermediate collection container, and
the pattern is formed on an inner surface of each of the internal collection container, the intermediate collection container, and the external collection container.

7. The bowl of claim 1, wherein the pattern is formed over an entire region of the inner surface.

8. The bowl of claim 1, wherein the pattern is formed in a partial region of the inner surface.

9. The bowl of claim 1, wherein the pattern includes a first pattern extended in a first direction parallel to a longitudinal direction of the collection container.

10. The bowl of claim 1, wherein the pattern includes a second pattern extended in a second direction perpendicular to a longitudinal direction of the collection container.

11. The bowl of claim 1, wherein the pattern includes a first pattern extended in a first direction parallel to a longitudinal direction of the collection container, and a second pattern extended in a second direction perpendicular to the first direction.

12.-17. (canceled)

18. An apparatus for treating a substrate, the apparatus comprising:
a support unit configured to support the substrate;
a nozzle configured to supply a treatment liquid onto the substrate; and
a bowl configured to accommodate the support unit,
wherein a pattern is formed on an inner surface of the bowl.

19. The apparatus of claim 18, wherein the bowl includes a plurality of grooves depressed from the inner surface, and
the pattern is formed by continuously arranging the plurality of grooves,
wherein the pattern includes a plurality of vertices formed between adjacent grooves among the plurality of grooves,
wherein a droplet of the treatment liquid scattered from a substrate rotated by the support unit is attached to the inner surface of the bowl, and
a contact angle between a virtual surface connecting the plurality of vertices and the droplet is 150° or more.

20. The apparatus of claim 18, wherein the pattern is formed in a partial region of the inner surface, and
the pattern is formed from an upper end of the bowl to a region corresponding to a process position of the substrate.
